(19) United States
(12) Patent Application Publication
(10) Pub. No.: US 2026/0293299 A1
(43) Pub. Date: Sep. 24, 2026

(54) SEMICONDUCTOR PACKAGE

(71) Applicant: SAMSUNG ELECTRONICS CO., LTD., Suwon-si (KR)

(72) Inventor: Sungmin Kim, Suwon-si (KR)

(73) Assignee: SAMSUNG ELECTRONICS CO., LTD., Suwon-si (KR)

(21) Appl. No.: 19/360,065

(22) Filed: Oct. 16, 2025

(30) Foreign Application Priority Data
Mar. 18, 2025 (KR) 10-2025-0034807

(51) Int. Cl. H10D 84/83; H10W 20/42; H10W 74/10; H10W 90/00

(52) U.S. Cl. CPC H10D 84/832; H10W 20/42; H10W 74/131; H10W 90/00

(57) ABSTRACT

A semiconductor package includes a base structure, a first logic chip electrically connected to the base structure, and a second logic chip that is electrically connected to the base structure and that is spaced apart from the first logic chip in a first direction parallel to an upper surface of the base structure. The first logic chip includes a first fin pattern, a semiconductor pattern spaced apart from the first fin pattern, a first source/drain pattern connected to the semiconductor pattern, and a first gate electrode overlapping with the semiconductor pattern. The second logic chip includes a second fin pattern, a channel pattern connected to the second fin pattern, a second source/drain pattern connected to the channel pattern, and a second gate electrode overlapping with the channel pattern.

### CROSS-REFERENCE TO RELATED APPLICATION

This U.S. non-provisional patent application claims priority under 35 U.S.C. §119 to Korean Patent Application No. 10-2025-0034807, filed on Mar. 18, 2025, in the Korean Intellectual Property Office, the entire contents of which being hereby incorporated by reference.

### BACKGROUND

A semiconductor package is a structure that includes integrated circuit chips and that is suitable for use in electronics. Typically, the semiconductor package comprises a semiconductor chip on a printed circuit board and the semiconductor chip is electrically connected to the printed circuit board using bonding wires or bumps. With the development of the electronics industry, various studies for improving the reliability of semiconductor packages have been conducted.

### SUMMARY

According to an aspect of one or more embodiments, a semiconductor package may comprise a base structure; a first logic chip electrically connected to the base structure; and a second logic chip that is electrically connected to the base structure and that is spaced apart from the first logic chip in a first direction parallel to an upper surface of the base structure. The first logic chip comprises a first fin pattern; a semiconductor pattern spaced apart from the first fin pattern; a first source/drain pattern connected to the semiconductor pattern; and a first gate electrode overlapping with the semiconductor pattern. The second logic chip comprises a second fin pattern; a channel pattern connected to the second fin pattern; a second source/drain pattern connected to the channel pattern; and a second gate electrode overlapping with the channel pattern.

According to another aspect of one or more embodiments, a semiconductor package may comprise a base structure; a first logic chip electrically connected to the base structure; and a second logic chip that is electrically connected to the base structure and that is spaced apart from the first logic chip in a first direction parallel to an upper surface of the base structure. The first logic chip comprises a plurality of semiconductor patterns; a first source/drain pattern connected to the plurality of semiconductor patterns; and a first gate electrode overlapping with the plurality of semiconductor patterns. The second logic chip comprises a channel pattern; a second source/drain pattern connected to the channel pattern; and a second gate electrode overlapping with the channel pattern. The first gate electrode overlaps with the plurality of semiconductor patterns and comprises a portion disposed between the plurality of semiconductor patterns.

According to yet another aspect of one or more embodiments, a semiconductor package may comprise a base structure; a first logic chip electrically connected to the base structure; a second logic chip that is electrically connected to the base structure and that is spaced apart from the first logic chip in a first direction parallel to an upper surface of the base structure; and a molding layer surrounding the first logic chip and the second logic chip. The first logic chip comprises a semiconductor pattern; a first source/drain pattern connected to the semiconductor pattern; a first gate electrode overlapping with the semiconductor pattern; a first gate insulating layer that separates the semiconductor pattern from the first gate electrode; a first active contact connected to the first source/drain pattern; and a first power line electrically connected to the first active contact. The second logic chip comprises a channel pattern; a second source/drain pattern connected to the channel pattern; a second gate electrode overlapping with the channel pattern; a second gate insulating layer that separates the channel pattern from the second gate electrode; a second active contact connected to the second source/drain pattern; and a second power line electrically connected to the second active contact. A maximum width of the first gate electrode in the first direction is greater than a maximum width of a second gate electrode in the first direction.

According to still yet another aspect of one or more embodiments, a method of fabricating a semiconductor package may comprise forming a first logic chip; forming a second logic chip; and mounting the first logic chip and the second logic chip on a base structure. The first logic chip comprises a first fin pattern; a semiconductor pattern spaced apart from the first fin pattern; a first source/drain pattern connected to the semiconductor pattern; and a first gate electrode overlapping with the semiconductor pattern. The second logic chip comprises a second fin pattern; a channel pattern connected to the second fin pattern; a second source/drain pattern connected to the channel pattern; and a second gate electrode overlapping with the channel pattern.

### BRIEF DESCRIPTION OF THE DRAWINGS

FIG. 1 is a top view of a semiconductor package according to some embodiments.

FIG. 2 is a cross-sectional view taken along line A1-A1′ in FIG. 1.

FIG. 3 is an enlarged view of a Q1 region of FIG. 1.

FIG. 4 is an enlarged view of a Q2 region of FIG. 1.

FIG. 5 is a cross-sectional view taken along line B1-B1′ in FIG. 3.

FIG. 6 is a cross-sectional view taken along line B2-B2′ in FIG. 4.

FIG. 7 is a cross-sectional view taken along line B3-B3′ in FIG. 3.

FIG. 8 is a cross-sectional view taken along line B4-B4′ in FIG. 4.

FIG. 9 is a cross-sectional view taken along line B5-B5′ in FIG. 3.

FIG. 10 is a cross-sectional view taken along line B6-B6′ in FIG. 4.

FIG. 11 is a top view of a semiconductor package according to some embodiments.

FIG. 12 is a cross-sectional view taken along line A2-A2′ in FIG. 11.

FIG. 13 is an enlarged view of a Q3 region of FIG. 12.

### DETAILED DESCRIPTION

Example embodiments will now be described more fully with reference to the accompanying drawings, in which various example embodiments are shown.

Hereinafter, a semiconductor package and a manufacturing method thereof according to embodiments will be described in detail with reference to the drawings. As used in this specification, a phrase using the form “at least one of A, B, or C” includes within its scope “only A”, “only B”, “only C”, “A and B”, “A and C”, “B and C” and “A, B, and C.”

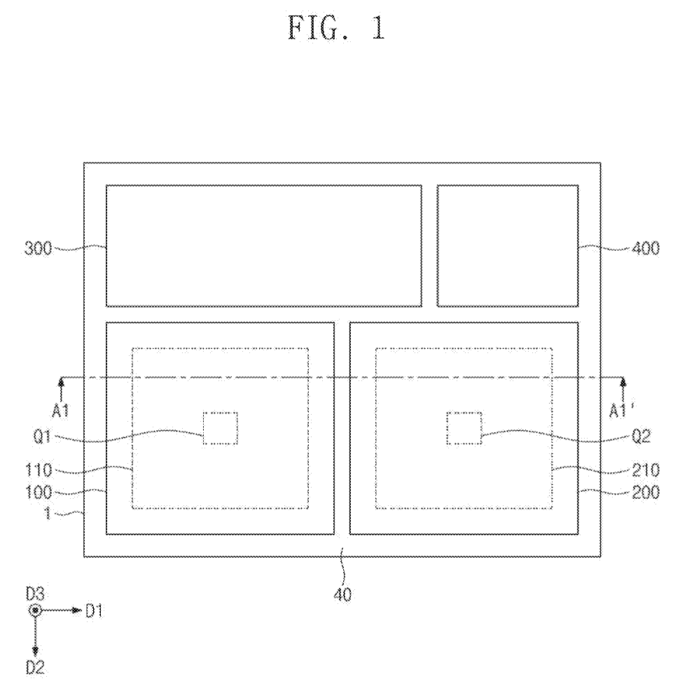

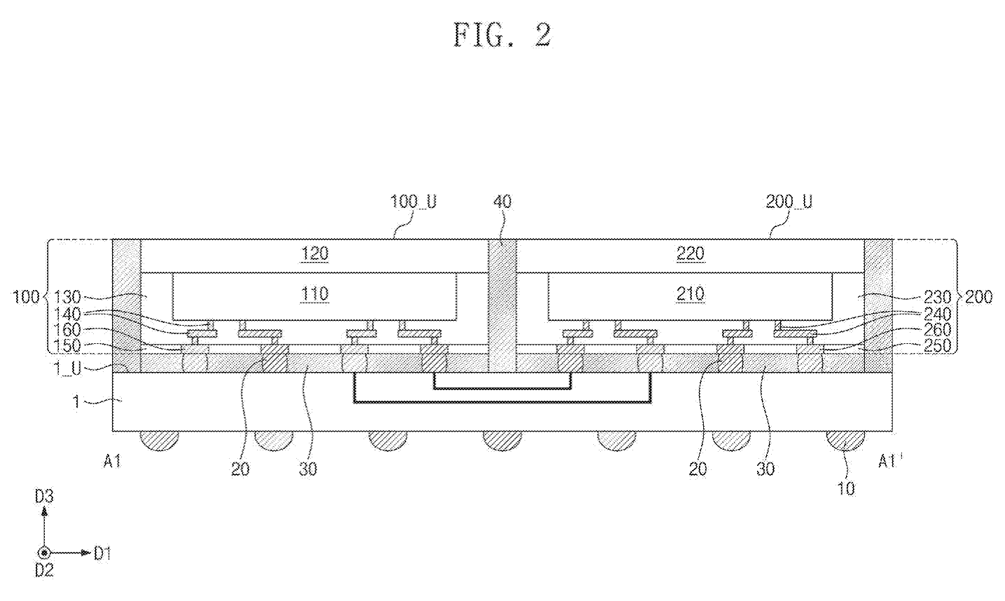

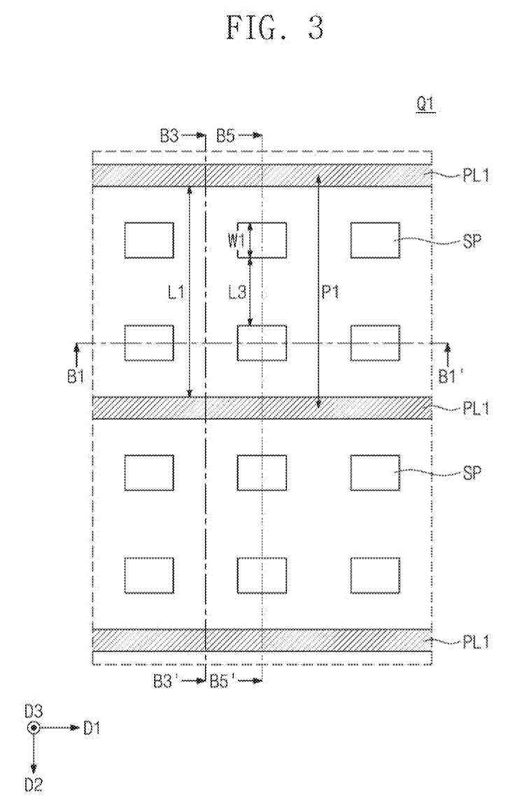

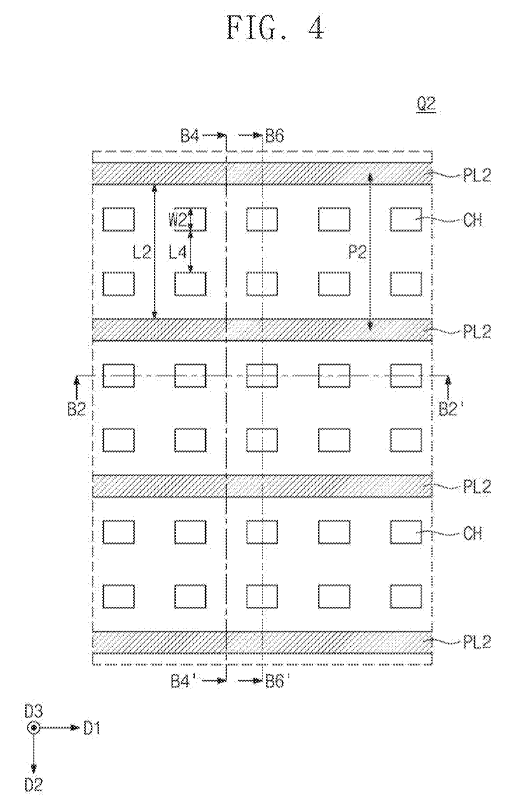

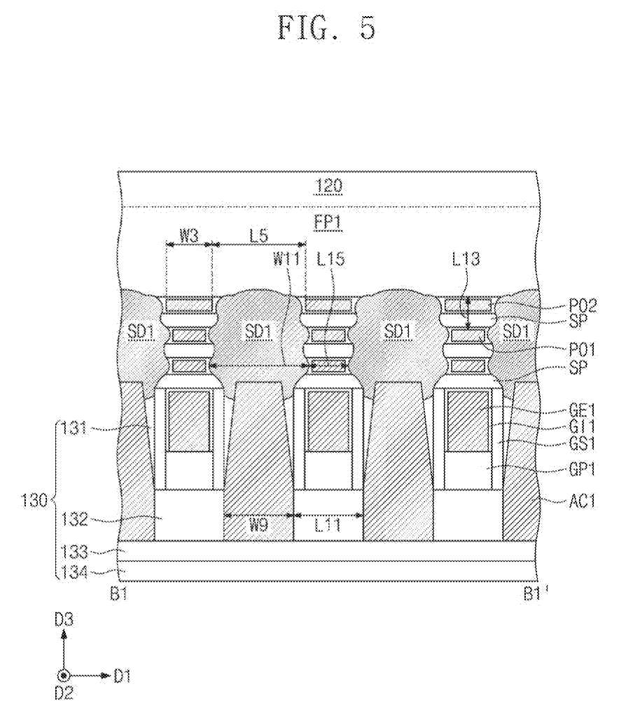

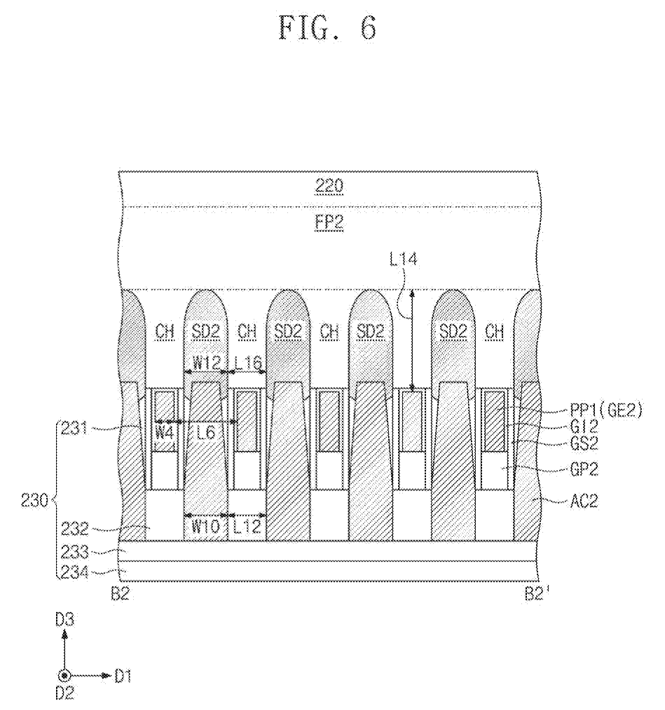

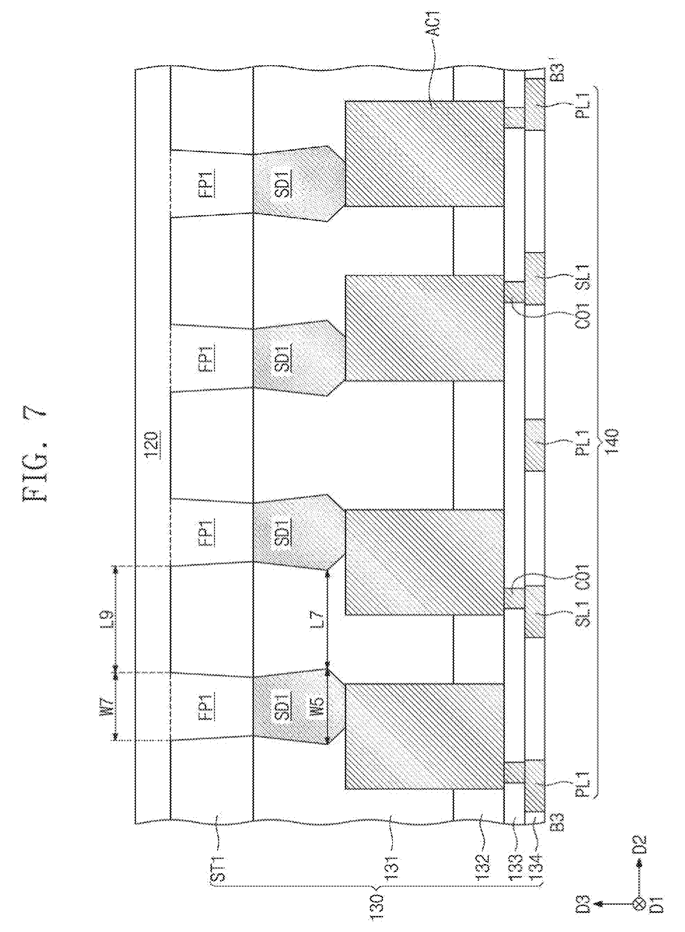

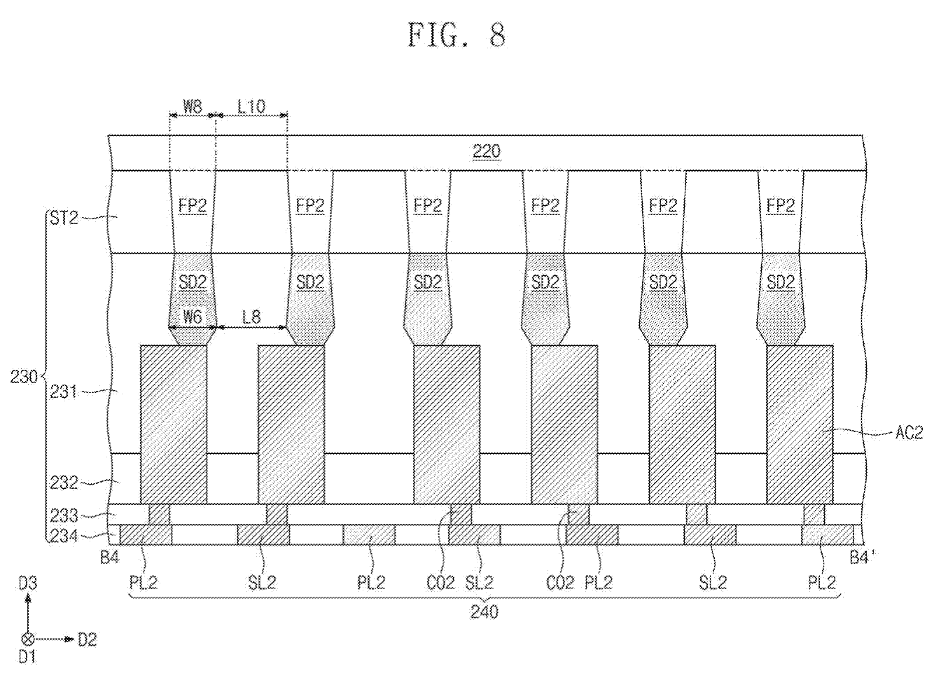

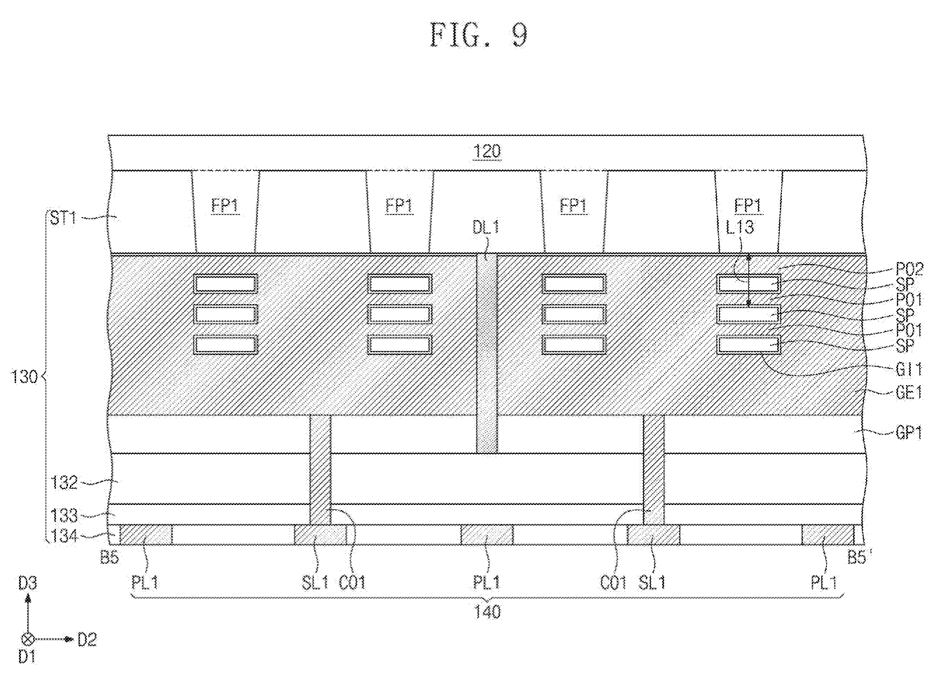

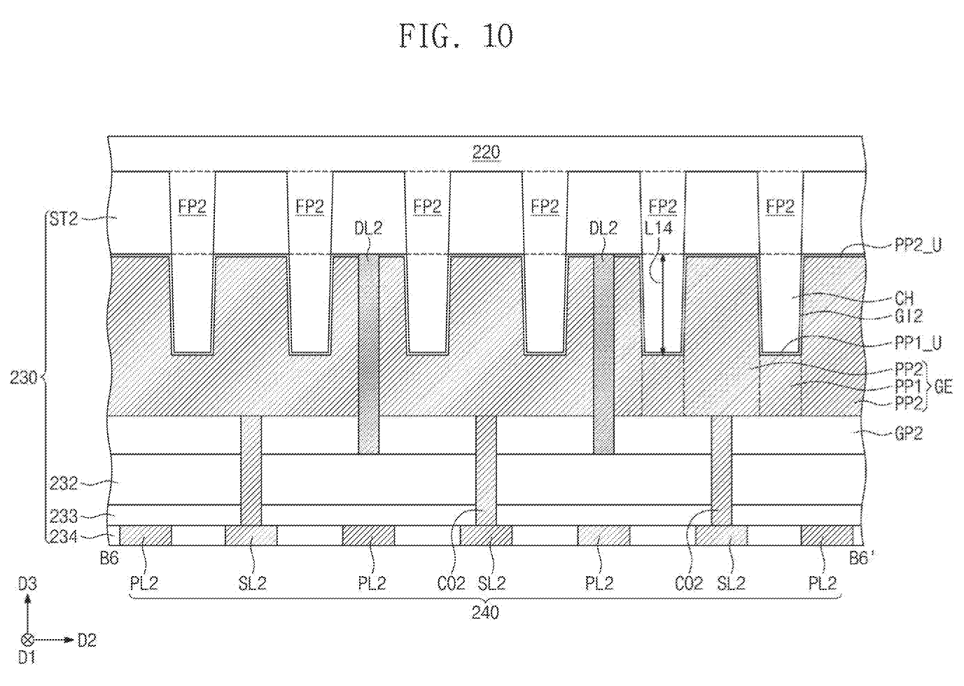

FIG. 1 is a top view of a semiconductor package according to some embodiments. FIG. 2 is a cross-sectional view taken along line A1-A1′ in FIG. 1. FIG. 3 is an enlarged view of a Q1 region of FIG. 1. FIG. 4 is an enlarged view of a Q2 region of FIG. 1. FIG. 5 is a cross-sectional view taken along line B1-B1′ in FIG. 3. FIG. 6 is a cross-sectional view taken along line B2-B2′ in FIG. 4. FIG. 7 is a cross-sectional view taken along line B3-B3′ in FIG. 3. FIG. 8 is a cross-sectional view taken along line B4-B4′ in FIG. 4. FIG. 9 is a cross-sectional view taken along line B5-B5′ in FIG. 3. FIG. 10 is a cross-sectional view taken along line B6-B6′ in FIG. 4.

Referring to FIGS. 1 and 2, the semiconductor package may include a terminal 10, a base structure 1, a bump 20, an underfill layer 30, a first logic chip 100, a second logic chip 200, a memory chip 300, an input/output chip 400, and a molding layer 40.

The base structure 1 may have a shape of a plate extending along a plane defined by a first direction D1 and a second direction D2. The first direction D1 and the second direction D2 may intersect with each other. As an example, the first direction D1 and the second direction D2 may be horizontal directions orthogonal to each other. The base structure 1 may be, for example, a printed circuit board (PCB), a silicon interposer, or a redistribution substrate.

The terminal 10 may be connected to the base structure 1. The terminal 10 may include a conductive material. The terminal 10 may include a plurality of terminals.

The first logic chip 100, the second logic chip 200, the memory chip 300, and the input/output chip 400 may be mounted on the base structure 1. The first logic chip 100, the second logic chip 200, the memory chip 300, and the input/output chip 400 may overlap with the base structure 1 in a third direction D3. The third direction D3 may intersect the first direction D1 and with the second direction D2. As an example, the third direction D3 may be a vertical direction orthogonal to the first direction D1 and the second direction D2.

The first logic chip 100 and the second logic chip 200 may be spaced apart from each other in the first direction D1. The first logic chip 100 and the memory chip 300 may be spaced apart from each other in the second direction D2. The input/output chip 400 and the second logic chip 200 may be spaced apart from each other in the second direction D2. The first direction D1 and the second direction D2 may be parallel to an upper surface 1_U of the base structure 1. The first logic chip 100, the second logic chip 200, the memory chip 300, and the input/output chip 400 may not overlap with each other in the third direction D3. In some embodiments, the first logic chip 100 and the second logic chip 200 may be spaced apart from each other in the second direction D2.

The first logic chip 100, the second logic chip 200, the memory chip 300, and the input/output chip 400 may be disposed at the same level as each other with respect to the upper surface 1_U of the base structure 1. An upper surface 100_U of the first logic chip 100 and an upper surface 200_U of the second logic chip 200 may be coplanar.

In the present disclosure, spatially relative terms may include other directions depending on use or operation of the semiconductor package in addition to directions shown in the drawings. For example, “an upper surface of A” may include both an upper surface and a lower surface of A. For example, “A is placed at a level lower than B” may include both A being placed at a level less than B, and A being placed at a level higher than B.

The bump 20 may be provided between the base structure 1 and the first logic chip 100, between the base structure 1 and the second logic chip 200, between the base structure 1 and the memory chip 300, and/or between the base structure 1 and the input/output chip 400. The first logic chip 100, the second logic chip 200, the memory chip 300, and the input/output chip 400 may be electrically connected to the base structure 1 through the bump 20. The first logic chip 100 and the second logic chip 200 may be electrically connected through the bump 20 and the base structure 1. The bump 20 may include a conductive material. The bump 20 may include a plurality of bumps.

The underfill layer 30 may be provided between the base structure 1 and the first logic chip 100, between the base structure 1 and the second logic chip 200, between the base structure 1 and the memory chip 300, and/or between the base structure 1 and the input/output chip 400. The underfill layer 30 may surround the bump 20. The underfill layer 30 may include a polymer material.

In some embodiments, at least one of the first logic chip 100, the second logic chip 200, the memory chip 300, or the input/output chip 400 may be in direct contact with the base structure 1 without the bump 20 and the underfill layer 30. For example, at least one of the first logic chip 100, the second logic chip 200, the memory chip 300, or the input/output chip 400 may be in direct contact with the base structure 1 through hybrid-bonding.

The molding layer 40 may surround the first logic chip 100, the second logic chip 200, the memory chip 300, and the input/output chip 400. The molding layer 40 may be provided on the base structure 1. The molding layer 40 may include a polymer material.

The first logic chip 100 and the second logic chip 200 may include, for example, a central processing unit (CPU), a graphics processing unit (GPU), or an application processor (AP).

The memory chip 300 may be a volatile memory chip or a non-volatile memory chip. The volatile memory chip may be, for example, a dynamic random access memory (DRAM), static RAM (SRAM), a thyristor RAM (TRAM), a zero capacitor RAM (ZRAM), or a twin transistor RAM (TTRAM). The non-volatile memory chip may be, for example, a flash memory, a magnetic RAM (MRAM), a spin-transfer torque MRAM (STT-MRAM), a ferroelectric RAM (FRAM), a phase change RAM (PRAM), a resistive RAM (RRAM), a polymer RAM (polymer RAM), or an insulator resistance change memory. In some embodiments, a plurality of memory chips stacked in the third direction D3 may be provided. As an example, a high bandwidth memory (HBM) may be provided.

The input/output chip 400 may include an input/output interface circuit. The input/output chip 400 may function as an interface between a peripheral input/output device and the first logic chip 100, the second logic chip 200, and/or the memory chip 300.

The first logic chip 100 may include a first logic cell structure 110, a first substrate 120, a first insulating structure 130, a first conductive structure 140, a first lower insulating layer 150, and a first lower pad 160.

The first substrate 120 may be a semiconductor substrate, an insulator substrate, or a semiconductor-on-insulator (SOI) substrate. The semiconductor substrate may comprise, for example, silicon, germanium, silicon-germanium, GaP or GaAs.

The first logic cell structure 110 may be connected to a lower surface of the first substrate 120.

The first conductive structure 140 may be electrically connected to the first logic cell structure 110. The first conductive structures 140 may include at least one of a conductive via, a conductive line, or a conductive pad. The first conductive structure 140 may include a conductive material.

The first insulating structure 130 may surround the first logic cell structure 110 and the first conductive structure 140. The first conductive structure 140 may be disposed in the first insulating structure 130. The first insulating structure 130 may be connected to the lower surface of the first substrate 120. The first insulating structure 130 may include an insulating material. In some embodiments, the first insulating structure 130 may be a multiple layer including a plurality of insulating layers.

The first lower pad 160 may be in contact with the bump 20. The first lower pad 160 may include a conductive material. The first lower pad 160 may include a plurality of first lower pads.

The first lower insulating layer 150 may surround the first lower pad 160. The first lower pad 160 may be disposed in the first lower insulating layer 150. The first lower insulating layer 150 may include an insulating material. In some embodiments, the first lower insulating layer 150 may be a multiple layer including a plurality of insulating layers.

The second logic chip 200 may include a second logic cell structure 210, a second substrate 220, a second insulating structure 230, a second conductive structure 240, a second lower insulating layer 250, and a second lower pad 260.

The second substrate 220 may be a semiconductor substrate, an insulator substrate, or a semiconductor-on-insulator (SOI) substrate.

The second logic cell structure 210 may be connected to a lower surface of the second substrate 220. An integration density of first cell transistors of the first logic cell structure 110 of the first logic chip 100 may be less than an integration density of second cell transistors of the second logic cell structure 210 of the second logic chip 200. A size of each of the first cell transistors may be larger than a size of each of the second cell transistors.

The second conductive structure 240 may be electrically connected to the second logic cell structure 210. The second conductive structures 240 may include at least one of a conductive via, a conductive line, or a conductive pad. The second conductive structure 240 may include a conductive material.

The second insulating structure 230 may surround the second logic cell structure 210 and the second conductive structure 240. The second conductive structure 240 may be disposed in the second insulating structure 230. The second insulating structure 230 may be connected to the lower surface of the second substrate 220. The second insulating structure 230 may include an insulating material. In some embodiments, the second insulating structure 230 may be a multiple layer including a plurality of insulating layers.

The second lower pad 260 may be in contact with the bump 20. The second lower pad 260 may include a conductive material. The second lower pad 260 may include a plurality of second lower pads.

The second lower insulating layer 250 may surround the second lower pad 260. The second lower pad 260 may be disposed in the second lower insulating layer 250. The second lower insulating layer 250 may include an insulating material. In some embodiments, the second lower insulating layer 250 may be a multiple layer including a plurality of insulating layers.

In some embodiments, a method of manufacturing the semiconductor package may include forming the first logic chip 100, forming the second logic chip 200, forming the memory chip 300, forming the input/output chip 400, and mounting the first logic chip 100, the second logic chip 200, the memory chip 300 and the input/output chip 400 on the base structure 1.

Referring to FIGS. 3, 5, 7, and 9, the first logic cell structure 110 may include a first fin pattern FP1, a semiconductor pattern SP, a first source/drain pattern SD1, a first gate electrode GE1, a first gate spacer GS1, a first gate insulating layer GI1, a first gate capping pattern GP1, a first gate isolation layer DL1, and a first active contact AC1.

The first fin pattern FP1, the semiconductor pattern SP, the first source/drain pattern SD1, the first gate electrode GE1, the first gate spacer GS1, the first gate insulating layer GI1, the first gate capping pattern GP1, the first gate isolation layer DL1, and the first active contact AC1 of the first logic cell structure 110 may be surrounded by the first insulating structure 130. The first insulating structure 130 may include a first device isolation layer ST1, a first insulating layer 131, a second insulating layer 132, a third insulating layer 133, and a fourth insulating layer 134. The first conductive structures 140 may include a first contact CO1, a first power line PL1, and a first signal line SL1. Each of the first contact CO1, the first power line PL1, and the first signal line SL1 may be provided in plural.

The first fin pattern FP1 may be a portion of the first substrate 120. A portion protruding from the lower surface of the first substrate 120 in a direction opposite to the third direction D3 may be defined as the first fin pattern FP1.

The first device isolation layer ST1 may fill a space between the first fin patterns FP1. The first device isolation layer ST1 may include an insulating material. In some embodiments, the first device isolation layer ST1 may be a multiple layer including a plurality of insulating layers.

In some embodiments, an upper portion of the first substrate 120 connecting the first fin pattern FP1 may be omitted. In this case, the first fin patterns FP1 may be separated from each other and may include, for example, an insulating material or a semiconductor material.

The first source/drain pattern SD1 may be connected to a lower surface of the first fin pattern FP1. The semiconductor pattern SP may be connected to the first source/drain pattern SD1. The first source/drain pattern SD1 may be epitaxial patterns formed by a selective epitaxial growth (SEG) process. The first source/drain pattern SD1 may include a semiconductor material. As an example, the first source/drain pattern SD1 may include at least one of silicon (Si), silicon-germanium (SiGe), or germanium (Ge). The first source/drain pattern SD1 may be doped with dopants.

A plurality of the semiconductor patterns SP may overlap with the first fin pattern FP1 in the third direction D3. The semiconductor pattern SP provided between the two first source/drain patterns SD1 adjacent to each other in the first direction D1 may overlap each other in the third direction D3. In some embodiments, the semiconductor pattern SP may include silicon (Si). For example, the semiconductor pattern SP may include crystalline silicon. In some embodiments, the semiconductor pattern SP may include silicon-germanium (SiGe).

The first gate electrode GE1 may overlap with the semiconductor pattern SP in the third direction D3. The first gate electrode GE1 may include a first portion PO1 provided between the semiconductor patterns SP and a second portion PO2 provided between one of the semiconductor patterns SP and the first fin pattern FP1. The first portion PO1 and the second portion PO2 of the first gate electrode GE1 may overlap with the semiconductor patterns SP in the third direction D3. The first portion PO1 of the first gate electrode GE1 may be disposed at a lower level than the second portion PO2 of the first gate electrodes GE1.

The first gate electrode GE1 and the semiconductor patterns SP may constitute a three-dimensional field effect transistor (e.g., MBCFET or GAAFET). The first gate electrode GE1 may include a conductive material.

The first gate insulating layer GI1 may be provided. The first gate insulating layer GI1 may be in contact with the first gate electrode GE1, the semiconductor pattern SP, and the first source/drain pattern SD1. The first gate insulating layer GI1 may separate the first gate electrode GE1 from the semiconductor pattern SP and the first source/drain pattern SD1. The first gate insulating layers GI1 may include an insulating material. For example, the first gate insulating layer GI1 may include an oxide.

The first gate spacer GS1 may be provided. A pair of first gate spacers GS1 may be disposed on both sides of the first gate electrode GE1. In other words, the first gate electrode GE1 may have a first gate spacer GS1 on each side thereof. The first insulating layer 131 may fill a space between the first gate spacers GS1. The first gate spacer GS1 may include an insulating material.

The first gate capping pattern GP1 may be provided. The first gate electrode GE1 may be provided on the first gate capping pattern GP1. The first gate isolation layer DL1 may separate the first gate electrodes GE1 in the first direction D1. The first gate isolation layer DL1, the first gate capping pattern GP1, and the first insulating layer 131 may be provided on the second insulating layer 132. The first gate capping pattern GP1 and the first gate isolation layer DL1 may include an insulating material.

The first active contact AC1 may be electrically connected to the first source/drain pattern SD1. The first active contact AC1 may penetrate the second insulating layer 132 and the first insulating layer 131 in the third direction D3. The first active contact AC1 may include a conductive material.

The second insulating layer 132 and the first active contact AC1 may be provided on the third insulating layer 133. A third insulating layer 133 may be provided on the fourth insulating layer 134. The first to fourth insulating layers 131, 132, 133, and 134 may include an insulating material.

The first power line PL1 and the first signal line SL1 may be provided in the fourth insulating layer 134. The first contact CO1 may connect the first power line PL1 and the first active contact AC1, connect the first signal line SL1 and the first active contact AC1, or connect the first signal line SL1 and the first gate electrode GE1.

Power may be supplied from the first power line PL1 through the first contact CO1 and the first active contact AC1. As an example, a power voltage (e.g., VDD or VSS) may be supplied from the first power line PL1 to the first source/drain pattern SD1 through the first contact CO1 and the first active contact AC1. The first power line PL1, the first signal line SL1, and the first contact CO1 may include a conductive material.

Referring to FIGS. 4, 6, 8, and 10, the second logic cell structure 210 may include a second fin pattern FP2, a channel pattern CH, a second source/drain pattern SD2, a second gate electrode GE2, a second gate spacer GS2, a second gate insulating layer GI2, a second gate capping pattern GP2, a second gate isolation layer DL2, and a second active contact AC2.

The second fin pattern FP2, the channel pattern CH, the second source/drain pattern SD2, the second gate electrode GE2, the second gate spacer GS2, the second gate insulating layer GI2, the second gate capping pattern GP2, the second gate isolation layer DL2, and the second active contact AC2 of the second logic cell structure 210 may be surrounded by the second insulating structure 230. The second insulating structure 230 may include a second device isolation layer ST2, a fifth insulating layer 231, a sixth insulating layer 232, a seventh insulating layer 233, and an eighth insulating layer 234. The second conductive structures 240 may include a second contact CO2, a second power line PL2, and a second signal line SL2.

The second fin pattern FP2 may be a portion of the second substrate 220. A portion protruding from the lower surface of the second substrate 220 in the direction opposite to the third direction D3 may be defined as the second fin pattern FP2.

The second device isolation layer ST2 may fill a space between the second fin patterns FP2. The second device isolation layer ST2 may include an insulating material. In some embodiments, the second device isolation layer ST2 may be a multiple layer including a plurality of insulating layers.

In some embodiments, an upper portion of the second substrate 220 connecting the second fin pattern FP2 may be omitted. In this case, the second fin patterns FP2 may be separated from each other and may include, for example, an insulating material or a semiconductor material.

The second source/drain pattern SD2 may be connected to a lower surface of the second fin pattern FP2. The channel pattern CH may be connected to the second source/drain pattern SD2. The second source/drain pattern SD2 may be an epitaxial pattern formed by a selective epitaxial growth (SEG) process. The second source/drain pattern SD2 may include a semiconductor material. As an example, the second source/drain pattern SD2 may include at least one of silicon (Si), silicon-germanium (SiGe), or germanium (Ge). The second source/drain pattern SD2 may be doped with dopants.

The channel pattern CH may overlap with the second fin pattern FP2 in the third direction D3. One channel pattern CH may be provided between two second source/drain patterns SD2 that are adjacent to each other in the first direction D1. In some embodiments, the channel pattern CH may include silicon (Si). For example, the channel pattern CH may include crystalline silicon. In some embodiments, the channel pattern CH may include silicon-germanium (SiGe).

The channel pattern CH and the second fin pattern FP2 may be portions of the second substrate 220. In other words, the channel pattern CH, the second fin pattern FP2, and the second substrate 220 may be connected to each other without a boundary to have an integral structure.

The second gate electrode GE2 may overlap with the channel pattern CH in the third direction D3. In an embodiment, the second gate electrode GE2 may include a first portion PP1 overlapping with the channel pattern CH in the third direction D3 and a second portion PP2 not overlapping with the channel pattern CH in the third directions D3. The first portions PP1 and the second portions PP2 of the second gate electrode GE2 may be alternately arranged with each other along the second direction D2. The first portion PP1 of the second gate electrode GE2 may connect the second portions PP2 of the second gate electrodes GE2. The first portion PP1 of the second gate electrode GE2 may be disposed between the second portions PP2 of the second gate electrodes GE2. The second portion PP2 of the second gate electrode GE2 may connect the first portions PP1 of the second gate electrodes GE2. The second portion PP2 of the second gate electrode GE2 may be disposed between the first portions PP1 of the second gate electrodes GE2.

The first portion PP1 of the second gate electrode GE2 may be disposed at a lower level than the channel pattern CH. An upper surface PP1_U of the first portion PP1 of the second gate electrode GE2 may be disposed at a lower level than the channel pattern CH. The upper surface PP1_U of the first portion PP1 of the second gate electrode GE2 may be disposed at a lower level than an upper surface PP2_U of the second portion PP2 of the second gate electrodes GE2. The second gate electrode GE2 and the channel pattern CH may constitute, for example, a FinFET. The second gate electrode GE2 may include a conductive material.

The second gate insulating layer GI2 may be provided. The second gate insulating layer GI2 may be in contact with the second gate electrode GE2 and the channel pattern CH. The second gate insulating layer GI2 may be spaced apart from the second source/drain pattern SD2. A second gate spacer GS2 may be provided between the second gate insulating layer GI2 and the second source/drain pattern SD2. The second gate insulating layer GI2 may separate the second gate electrode GE2 from the channel pattern CH. The second gate insulating layer GI2 may include an insulating material. For example, the second gate insulating layer GI2 may include an oxide.

The second gate spacer GS2 may be provided. A pair of second gate spacers GS2 may be disposed on both sides of the second gate electrode GE2. In other words, the second gate electrode GE2 may have a second gate spacer GS2 on each side thereof. The fifth insulating layer 231 may fill a space between the second gate spacers GS2. The second gate spacer GS2 may include an insulating material.

The second gate capping pattern GP2 may be provided. The second gate electrode GE2 may be provided on the second gate capping pattern GP2. The second gate isolation layer DL2 may separate the second gate electrodes GE2 in the first direction D1. The second gate isolation layer DL2, the second gate capping pattern GP2, and the fifth insulating layer 231 may be provided on the sixth insulating layer 232. The second gate capping pattern GP2 and the second gate isolation layer DL2 may include an insulating material.

The second active contact AC2 may be electrically connected to the second source/drain pattern SD2. The second active contact AC2 may penetrate the sixth insulating layer 232 and the fifth insulating layer 231 in the third direction D3. The second active contacts AC2 may include a conductive material.

The sixth insulating layer 232 and the second active contact AC2 may be provided on the seventh insulating layer 233. The seventh insulating layer 233 may be provided on the eighth insulating layer 234. The fifth to eighth insulating layers 231, 232, 233, and 234 may include an insulating material.

The second power line PL2 and the second signal line SL2 may be provided in the eighth insulating layer 234. The second contact CO2 may connect the second power line PL2 and the second active contact AC2, connect the second signal line SL2 and the second active contact AC2, or connect the second signal line SL2 and the second gate electrode GE2.

Power may be supplied from the second power line PL2 through the second contact CO2 and the second active contact AC2. As an example, a power voltage (e.g., VDD or VSS) may be supplied from the second power line PL2 to the second source/drain pattern SD2 through the second contact CO2 and the second active contact AC2. The second power line PL2, the second signal line SL2, and the second contact CO2 may include a conductive material.

Referring to FIGS. 3, 4, 5, 6, 7, 8, 9, and 10, the first and second power lines PL1, PL2 may extend in the first direction D1. The first power lines PL1 may be arranged to be spaced apart from each other in the second direction D2. The second power lines PL2 may be arranged to be spaced apart from each other in the second direction D2. A distance L1 in the second direction D2 between the first power lines PL1 adjacent to each other in the second direction D2 may be greater than a distance L2 in the second direction D2 between the second power lines PL2 adjacent to each other in the second direction D2. In the present disclosure, a distance of two components may mean, for example, the shortest distance between the two components. A pitch P1 in the second direction D2 between the first power lines PL1 adjacent to each other in the second direction D2 may be greater than a pitch P2 in the second direction d2 between the second power lines PL2 adjacent to each other in the second direction D2.

The semiconductor pattern SP may be spaced apart from the first fin pattern FP1 in the third direction D3. The channel pattern CH may be connected to the second fin pattern FP2.

A maximum width W1 of the semiconductor pattern SP in the second direction D2 may be greater than a maximum width W2 of the channel pattern CH in the second direction D2. A distance L3 in the second direction D2 between the semiconductor pattern SP adjacent to each other in the second direction D2 may be greater than a distance L4 in the second direction D2 between the channel patterns CH adjacent to each other in the second direction D2.

A pitch in the first direction D1 of the semiconductor patterns SP that are adjacent to each other in the first direction D1 may be greater than a pitch in the first direction D1 of the channel patterns CH that are adjacent to each other In the first direction D1. A pitch in the second direction D2 of the semiconductor patterns SP that are adjacent to each other in the second direction D2 may be greater than a pitch in the second direction D2 of the channel patterns CH that are adjacent to each other in the second direction D2.

A maximum width W3 of the first gate electrode GE1 in the first direction D1 may be greater than a maximum width W4 of the second gate electrode GE2 in the first directionD1. A distance L5 in the first direction D1 between the first gate electrodes GE1 adjacent to each other in the first direction D1 may be greater than a distance L6 in the first direction D1 between the second gate electrodes GE2 adjacent to each other in the first direction D1. A pitch in the first direction D1 of the first gate electrodes GE1 adjacent to each other in the first direction D1 may be greater than a pitch in the first direction D1 of the second gate electrodes GE2 adjacent to each other in the first direction D1.

A maximum width W5 of the first source/drain pattern SD1 in the second direction D2 may be greater than a maximum width W6 of the second source/drain pattern SD2 in the second direction D2. A distance L7 in the second direction D2 between the first source/drain patterns SD1 adjacent to each other in the second direction D2 may be greater than a distance L8 in the second direction D2 between the second source/drain patterns SD2 adjacent to each other in the second direction D2.

A pitch in the first direction D1 of the first source/drain patterns SD1 adjacent to each other in the first direction D1 may be greater than a pitch in the first direction D1 of the second source/drain patterns SD2 adjacent to each other in the first direction D1. A pitch in the second direction D2 of the first source/drain patterns SD1 adjacent to each other in the second direction D2 may be greater than a pitch in the second direction D2 of the second source/drain pattern SD2 adjacent to each other in the second direction D2.

A maximum width W7 of the first fin pattern FP1 in the second direction D2 may be greater than a maximum width W8 of the second fin pattern FP2 in the second direction D2. A distance L9 in the second direction D2 between the first fin patterns FP1 adjacent to each other in the second direction D2 may be greater than a distance L10 in the second direction D2 between the second fin patterns FP2 adjacent to each other in the second direction D2. A pitch in the second direction D2 of the first fin patterns FP1 adjacent to each other in the second direction D2 may be greater than a pitch in the second direction D2 of the second fin patterns FP2 adjacent to each other in the second direction D2.

A maximum width W9 of the first active contact AC1 in the first direction D1 may be greater than a maximum width W10 of the second active contact AC2 in the first direction D1. A distance L11 in the first direction D1 between the first active contacts AC1 adjacent to each other in the first direction D1 may be greater than a distance L12 in the first direction D1 between the second active contacts AC2 adjacent to each other in the first direction D1. A pitch in the first direction D1 of the first active contacts AC1 adjacent to each other in the first direction D1 may be greater than a pitch in the first direction D1 of the second active contacts AC2 adjacent to each other in the first direction D1.

The first and second portions PO1, PO2 of the first gate electrode GE1 may be disposed at a higher level than the first portion PP1 of the second gate electrode GE2. A distance L13 in the third direction D3 between the first portion PO1 of the first gate electrode GE1 and the first fin pattern FP1 may be smaller than a distance L14 in the third directionD3 between the first portion PP1 of the second gate electrode GE2 and the second fin pattern FP2.

A maximum width W11 of the first source/drain pattern SD1 in the first direction D1 may be greater than a maximum width W12 of the second source/drain pattern SD2 in the first direction D1. A distance L15 in the first direction D1 between the first source/drain patterns SD1 adjacent to each other in the first direction D1 may be greater than a distance L16 in the first direction D1 between the second source/drain pattern SD2 adjacent to each other in the first direction D1.

In some embodiments, a power voltage applied to the first logic chip 100 may be higher than that applied to the second logic chip 200.

MBCFETs are advantageous in terms of high performance (e.g., operating speed) compared to FinFETs, but have relatively large parasitic capacitance at low power and high transistor integration density. FinFETs have relatively small parasitic capacitance at low power and high transistor integration density compared to MBCFETs, but are disadvantageous in terms of high performance. The semiconductor package according to some embodiments may include the first logic chip 100 having a high performance (e.g., such as the MBCFET) and the second logic chip 200 having a low power and high transistor integration density (e.g., such as the FinFET) , thereby optimizing performance and efficiency of power of the semiconductor package.

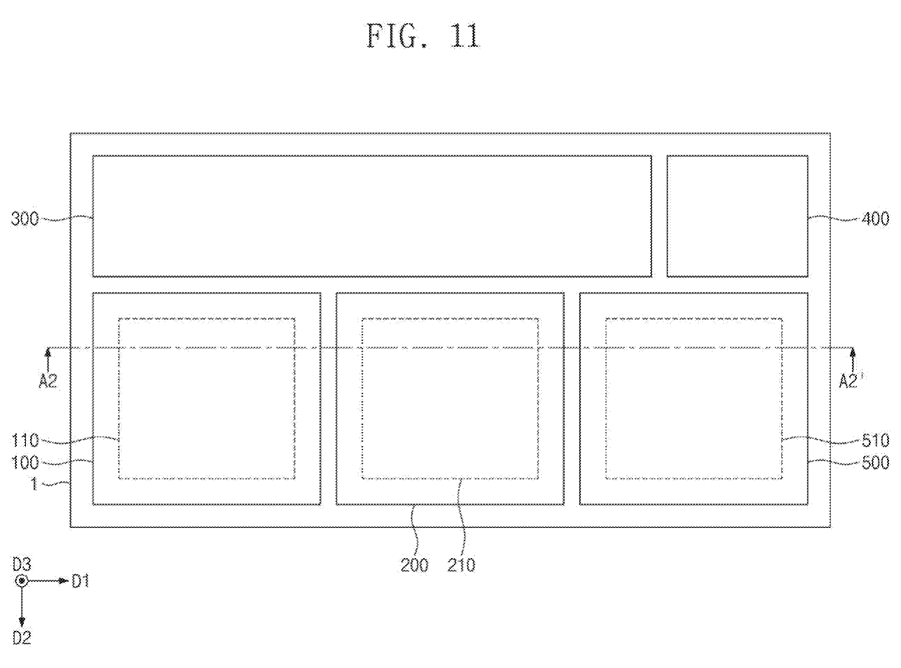

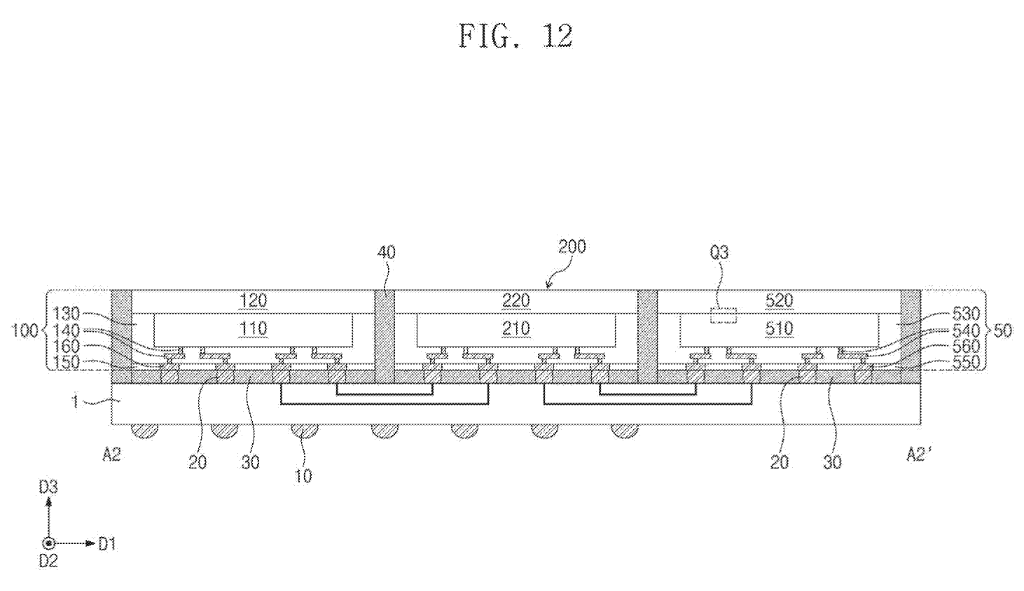

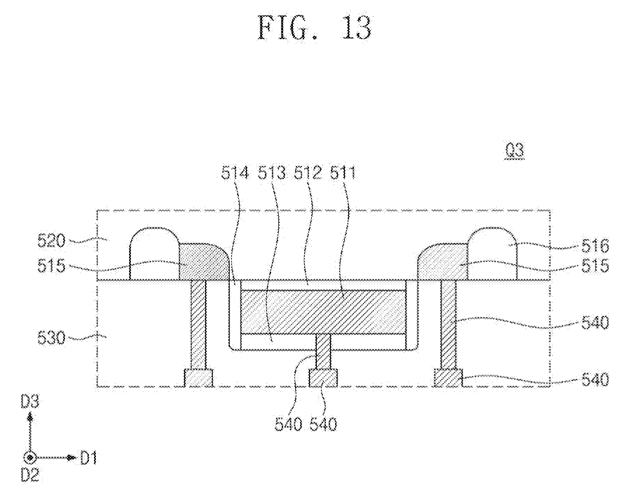

FIG. 11 is a top view of a semiconductor package according to some embodiments. FIG. 12 is a cross-sectional view taken along line A2-A2′ in FIG. 11. FIG. 13 is an enlarged view of a Q3 region of FIG. 12. The semiconductor package according to FIGS. 11, 12 and 13 may be similar to the semiconductor package according to FIG. 1 to FIG. 10 except as described below. Like reference designators refer to like components and repeated description thereof is omitted for conciseness.

Referring to FIGS. 11 and 12, the semiconductor package may include the terminal 10, the base structure 1, the bump 20, the underfill layer 30, the first logic chip 100, the second logic chip 200, a third logic chip 500, the memory chip 300, the input/output chip 400, and the molding layer 40.

The third logic chip 500 may be mounted on the base structure 1. The third logic chip 500 may overlap with the base structure 1 in the third direction D3.

The first logic chip 100, the second logic chip 200, and the third logic chip 500 may be spaced apart from each other in the first direction D1. The first logic chip 100, the second logic chip 200, the third logic chip 500, the memory chip 300, and the input/output chip 400 may not overlap with each other in the third direction D3.

The bump 20 may be provided between the third logic chip 500 and the base structure 1. The third logic chip 500 may be electrically connected to the base structure 1 through the bump 20. The third logic chip 500 and the second logic chip 200 may be electrically connected through the bump 20 and the base structure 1. The underfill layer 30 may be provided between the third logic chip 500 and the base structure 1.

The location and connection of the first to third logic chips 100, 200, 500 is not limited to that shown in FIGS. 11 and 12. In some embodiments, the third logic chip 500 may be disposed between the first logic chip 100 and the second logic chip 200, and may be connected to the first logic chip100 and the second logic chip 200.

The third logic chip 500 may include, for example, a central processing unit (CPU), a graphics processing unit (GPU), or an application processor (AP).

The third logic chip 500 may include a third logic cell structure 510, a third substrate 520, a third insulating structure 530, a third conductive structure 540, a third lower insulating layer 550, and a third lower pad 560.

The third substrate 520 may be a semiconductor substrate, an insulator substrate, or a semiconductor-on-insulator (SOI) substrate. The third logic cell structure 510 may be connected to a lower surface of the third substrate 520.

The third conductive structure 540 may be electrically connected to the third logic cell structure 510. The third conductive structures 540 may include at least one of a conductive via, a conductive line, or a conductive pad. The third conductive structure 540 may include a conductive material.

The third insulating structure 530 may surround the third logic cell structure 510 and the third conductive structure 540. The third conductive structure 540 may be disposed in the third insulating structure 530. The third insulating structure 530 may be connected to the lower surface of the third substrate 520. The third insulating structure 530 may include an insulating material. In some embodiments, the third insulating structure 530 may be a multiple layer including a plurality of insulating layers.

The third lower pad 560 may be in contact with the bump 20. The third lower pad 560 may include a conductive material. The third lower pad 560 may include a plurality of third lower pads 560.

The third lower insulating layer 550 may surround the third lower pad 560. The third lower pad 560 may be disposed in the third lower insulating layer 550. The third lower insulating layer 550 may include an insulating material. In some embodiments, the third lower insulating layer 550 may be a multiple layer including a plurality of insulating layers.

Referring to FIG. 13, the third logic cell structure 510 of the third logic chip 500 may include a planar transistor. The third logic cell structure 510 may include a buried isolation layer 516, a third source/drain pattern 515, a third gate electrode 511, a third gate insulating layer 512, a third gate capping pattern 513, and third gate spacer 514.

The third source/drain pattern 515 may be provided within the third substrate 520. In some embodiments, the third source/drain pattern 515 may be portion of the third substrate 520. In an example, the third source/drain pattern 515 may be formed by doping the third substrate 520 with dopants. A portion of the third substrate 520 between the third source/drain patterns 515 may be defined as a channel region.

The buried isolation layer 516 may be provided in the third substrate 520. Third source/drain pattern 515 and a third gate electrode GE3 may be provided between the buried isolation layers 516. The buried isolation layer 516 may include an insulating material.

The third gate electrode 511 may be disposed between the third source/drain patterns 515. The third gate electrode 511 may include a conductive material.

The third gate insulating layer 512 may be provided on the third gate electrode 511. The third gate electrode 511 and the third substrate 520 may be spaced apart by the third gate insulating layer 512. The third gate insulating layer 512 may include an insulating material.

A third gate electrode 511 may be provided on the third gate capping pattern 513. The third gate spacers 514 may be disposed on both sides of the third gate electrode 511. The third gate capping pattern 513 and the third gate spacer 514 may include an insulating material.

Each of the third source/drain pattern 515 and the third gate electrode 511 may be electrically connected to the third conductive structure 540. The third insulating structure 530 may surround the third conductive structure 540 and the third gate electrode 511.

A semiconductor package according to some embodiments may include the first logic chip 100 including an MBCFET, the second logic chip 200 including a FinFET, and the third logic chip 500 including a planar FET. Accordingly, an efficiency of a performance and power of the semiconductor package may be optimized.

A semiconductor package according to various embodiments comprises a high performance logic chip and a low power and high transistor integration density logic chip, thereby optimizing performance and efficiency of power of the semiconductor package.

While various embodiments are described above with reference to the drawings, a person skilled in the art may understand that many modifications and variations are made without departing from the spirit and scope defined in the following claims. Accordingly, the example embodiments should be considered in all respects as illustrative and not restrictive, with the spirit and scope being indicated by the appended claims.

What is claimed is:

1. A semiconductor package comprising:
a base structure;
a first logic chip electrically connected to the base structure; and
a second logic chip that is electrically connected to the base structure and that is spaced apart from the first logic chip in a first direction parallel to an upper surface of the base structure,
wherein the first logic chip comprises:
a first fin pattern;
a semiconductor pattern spaced apart from the first fin pattern;
a first source/drain pattern connected to the semiconductor pattern; and
a first gate electrode overlapping with the semiconductor pattern, and
wherein the second logic chip comprises:
a second fin pattern;
a channel pattern connected to the second fin pattern;
a second source/drain pattern connected to the channel pattern; and
a second gate electrode overlapping with the channel pattern.

2. The semiconductor package of claim 1, wherein the first logic chip and the second logic chip are disposed at a same level with respect to the upper surface of the base structure.

3. The semiconductor package of claim 1, wherein an upper surface of the first logic chip and an upper surface of the second logic chip are coplanar.

4. The semiconductor package of claim 1, wherein the semiconductor pattern comprises a plurality of semiconductor patterns,
wherein the first gate electrode comprises a portion disposed between the plurality of semiconductor patterns,
wherein the second gate electrode comprises a portion overlapping with the channel pattern, and
wherein a distance between the portion of the first gate electrode and the first fin pattern is less than a distance between the portion of the second gate electrode and the second fin pattern.

5. The semiconductor package of claim 1, wherein a maximum width of the first source/drain pattern in the first direction is greater than a maximum width of the second source/drain pattern in the first direction,
wherein a maximum width of the first source/drain pattern in a second direction intersecting the first direction is greater than a maximum width of the second source/drain pattern in the second direction, and
wherein the second direction is parallel to the upper surface of the base structure.

6. The semiconductor package of claim 1, wherein a maximum width of the semiconductor pattern in the first direction is greater than a maximum width of the channel pattern in the first direction.

7. The semiconductor package of claim 1, wherein the first logic chip further comprises a first gate insulating layer that separates the semiconductor pattern from the first gate electrode,
wherein the second logic chip comprises a second gate insulating layer that separates the channel pattern from the second gate electrode,
wherein the first gate insulating layer is in contact with the first source/drain pattern, and
wherein the second gate insulating layer is spaced apart from the second source/drain pattern.

8. A semiconductor package comprising:
a base structure;
a first logic chip electrically connected to the base structure; and
a second logic chip that is electrically connected to the base structure and that is spaced apart from the first logic chip in a first direction parallel to an upper surface of the base structure,
wherein the first logic chip comprises:
a plurality of semiconductor patterns;
a first source/drain pattern connected to the plurality of semiconductor patterns; and
a first gate electrode overlapping with the plurality of semiconductor patterns,
wherein the second logic chip comprises:
a channel pattern;
a second source/drain pattern connected to the channel pattern; and
a second gate electrode overlapping with the channel pattern, and
wherein the first gate electrode overlaps with the plurality of semiconductor patterns and comprises a portion disposed between the plurality of semiconductor patterns.

9. The semiconductor package of claim 8, wherein the first logic chip comprises a first fin pattern that overlaps with the the plurality of semiconductor patterns and that is spaced apart from the the plurality of semiconductor patterns, and
wherein the second logic chip comprises a second fin pattern connected to the channel pattern.

10. The semiconductor package of claim 9, wherein a maximum width of the first fin pattern is greater than a maximum width of the second fin pattern.

11. The semiconductor package of claim 9, wherein the second gate electrode comprises a portion overlapping with the second fin pattern, and
wherein a distance between the portion of the first gate electrode and the first fin pattern is less than a distance between the portion of the second gate electrode and the second fin pattern.

12. The semiconductor package of claim 8, wherein a maximum width of the first gate electrode is greater than a maximum width of the second gate electrode.

13. The semiconductor package of claim 8, further comprising a memory chip that overlaps with the base structure and that does not overlap with the first logic chip and the second logic chip.

14. The semiconductor package of claim 8, wherein the first logic chip comprises first power lines,
wherein the second logic chip comprises second power lines, and
wherein a distance between the first power lines is greater than a distance between the second power lines.

15. The semiconductor package of claim 8, wherein an integration density of first cell transistors of the first logic chip is less than an integration density of second cell transistors of the second logic chip.

16. A semiconductor package comprising:
a base structure;
a first logic chip electrically connected to the base structure;
a second logic chip that is electrically connected to the base structure and that is spaced apart from the first logic chip in a first direction parallel to an upper surface of the base structure; and
a molding layer surrounding the first logic chip and the second logic chip,
wherein the first logic chip comprises:
a semiconductor pattern;
a first source/drain pattern connected to the semiconductor pattern;
a first gate electrode overlapping with the semiconductor pattern;
a first gate insulating layer that separates the semiconductor pattern from the first gate electrode;
a first active contact connected to the first source/drain pattern; and
a first power line electrically connected to the first active contact,
wherein the second logic chip comprises:
a channel pattern;
a second source/drain pattern connected to the channel pattern;
a second gate electrode overlapping with the channel pattern;
a second gate insulating layer that separates the channel pattern from the second gate electrode;
a second active contact connected to the second source/drain pattern; and
a second power line electrically connected to the second active contact, and
wherein a maximum width of the first gate electrode in the first direction is greater than a maximum width of the second gate electrode in the first direction.

17. The semiconductor package of claim 16, further comprising a third logic chip that is electrically connected to the base structure and that is spaced apart from the first logic chip and the second logic chip in the first direction,
wherein the third logic chip comprises a planar transistor.

18. The semiconductor package of claim 16, wherein a maximum width of the first active contact in the first direction is greater than a maximum width of the second active contact in the first direction.

19. The semiconductor package of claim 16, wherein the first gate electrode comprises two first gate electrodes that are adjacent to each other in the first direction,
wherein the second gate electrode comprises two second gate electrodes that are adjacent to each other in the first direction, and
wherein a distance between the two first gate electrodes in the first direction is greater than a distance between the two second gate electrodes in the first direction.

20. The semiconductor package of claim 16, wherein the first logic chip and the second logic chip are electrically connected to each other through the base structure.
